(19) United States
(12) Patent Application Publication
(10) Pub. No.: US 2026/0255934 A1
(43) Pub. Date: Aug. 27, 2026

(54) METHOD FOR MANUFACTURING GROUP 3 NITRIDE SEMICONDUCTOR TEMPLATE WITH IMPROVED BONDING LAYER QUALITY

(71) Applicant: WAVELORD CO., LTD, Hwaseong-si (KR)

(72) Inventors: Juneo SONG, Suwon-si (KR); Hyeong Seon YUN, Paju-si (KR); Young Hun HAN, Osan-si (KR); Ji Hyung MOON, Gunpo-si (KR)

(73) Assignee: WAVELORD CO., LTD, Hwaseong-si (KR)

(21) Appl. No.: 18/860,669

(22) PCT Filed: Jan. 17, 2024
(86) PCT No.: PCT/KR2024/000819

§ 371 Date: Oct. 27, 2024

(30) Foreign Application Priority Data
Sep. 14, 2023 (KR) 10-2023-0122283

(51) Int. Cl. H10P 95/90; H10P 10/00; H10P 14/20; H10P 54/20

(52) U.S. Cl. CPC H10P 95/904; H10P 10/126; H10P 14/3416; H10P 54/20

(57) ABSTRACT

The present invention relates to a method of manufacturing a group 3 nitride semiconductor template with improved bonding layer quality, and more specifically, to a method of manufacturing a group 3 nitride semiconductor template having a high-quality group 3 nitride semiconductor seed layer, which can significantly improve the quality of a bonding layer by performing annealing on the bonding layer in two stages depending on a temperature.

### TECHNICAL FIELD

The present invention relates to a method of manufacturing a group 3 nitride semiconductor template with improved bonding layer quality, and more specifically, to a method of manufacturing a group 3 nitride semiconductor template having a high-quality group 3 nitride semiconductor seed layer, which can significantly improve the quality of a bonding layer by performing annealing on the bonding layer in two stages depending on a temperature.

### BACKGROUND ART

In conventional GaN material-based power semiconductor (high electron mobility transistor (HEMT)) devices having a horizontal channel structure based on a technology that directly grows GaN materials on an Si single crystalline growth substrate wafer, in order for the corresponding device to be operated stably at high temperatures with high voltage and/or high-speed switching capabilities, a design that suppresses the leakage current of a power semiconductor device through high-quality epitaxial thin film growth technology with high breakdown voltage and high reliability characteristics is essential.

To this end, conventional group 3 nitride semiconductor thin film materials and power semiconductor devices using the same have a structure in which 1) an Si single crystalline growth substrate wafer having high electrical resistance characteristics, 2) a melt-back etching prevention layer containing AlN materials (a nitride or nitride oxide including an Al composition) for suppressing a melt-back etching phenomenon through reaction with a surface layer of the Si single crystalline growth substrate wafer at a high temperature, 3) a crack prevention compressive stress layer containing AlGaN materials (group III nitride including an Al or Ga composition), and 4) an active layer of the power semiconductor containing GaN materials (group III nitride including a Ga composition) are formed by being sequentially stacked.

In addition, the above-described active layer of the power semiconductor (HEMT) having the horizontal channel structure containing GaN materials is typically formed by stacking four regions: 1) a GaN buffer layer, 2) a GaN channel layer (horizontal transistor), 3) an AlGaN barrier layer, and 4) a capping passivation layer (depletion mode) or p-type nitride semiconductor layer (enhancement mode).

That is, in the conventional group III nitride power semiconductor (HEMT) device structure in which the GaN materials are grown directly on the Si single crystalline growth substrate wafer, the high-resistance Si single crystalline growth substrate wafer needs to be applied along under the GaN channel layer with the formation of a high resistance GaN buffer layer, but there are the following problems.

First, in the conventional group III nitride (GaN materials) power semiconductor (HEMT) device structure, a process of directly growing a GaN material-based single crystalline thin film and a power semiconductor device structure on an Si single crystalline wafer for a group III nitride power semiconductor growth substrate is performed using a metal organic chemical vapor deposition (MOCVD) device. In this case, a process of growing (depositing) the GaN material-based single crystalline thin film containing Ga atoms is basically performed at a high temperature of about 1000° C. and in a reducing atmosphere (H2, H+, NH3, radical ions), and the melt-back etching prevention film region for blocking Si—Ga metallic eutectic reactions from actively occurring between the Si single crystalline wafer surface layer and the Ga atoms with relatively small energy is absolutely needed.

The melt-back etching prevention film region may typically have a thickness of about 100 nm, and representatively includes an AlN material layer grown through an in-situ process in an MOCVD chamber. In addition, an AlN or AlNO material layer may be deposited on the Si single crystalline wafer for a group III nitride power semiconductor growth substrate through an ex-situ process before the Si single crystalline wafer is loaded into the MOCVD chamber using another external deposition process device (a sputtering, pulsed laser deposition (PLD), or atomic layer deposition (ALD) device).

However, when forming a melt-back etching prevention film area formed with the above-described AlN material layer on an Si single crystalline wafer for a growth substrate having electrically high resistance characteristics, there is a problem that although the level of damage to the surface of the Si growth substrate is less during AlN growth, the Si-Al metallic process reactions still occur entirely or locally on the surface of the Si growth substrate to form a conductive interface material layer, resulting in a deterioration in the crystal quality of GaN materials grown in a continuous process. In addition, there is a problem that the crystal quality deteriorates (crystallinity reduction) due to the formation of a conductive interface material (disordered SiAIN) caused by damage to the surface of the Si growth substrate, and as a result, a leakage current increases due to an increase in density of dislocations, which are major crystal defects, which ultimately promotes the insulation breakdown phenomenon.

Second, in the above-described conventional group III nitride (GaN material-based) power semiconductor (HEMT) device structure, when a material is grown (or deposited), a process needs to be performed in consideration of a lattice constant (LC) and coefficient of thermal expansion (CTE), which are material-specific values between different materials, and when the LC and CTE between the two materials are significantly different, micro or macro cracks inevitably occur in the grown (deposited) material thin film or crystal quality deteriorates due to structural stress and thermo-mechanical induced stress occurring during or after the growth (deposition) process. In particular, when GaN materials or AlN materials are directly grown (or deposited) on an Si single crystalline wafer for a group III nitride power semiconductor growth substrate, strong tensile stress is generated in terms of the CTE and/or the LC, and thus not only cracks may be easily observed, but also a device with a high breakdown voltage and high reliability may be implemented through the growth to a predetermined thickness or more. However, a thickness of the group III nitride power semiconductor device structure cannot be increased due to the tensile stress.

Although various technologies have been devised as a method of relieving the above-described tensile stress or suppressing cracks, as a way to introduce a material and process of artificially generating compressive stress to compensate for and buffer tensile stress, a crack prevention compressive stress layer that suppresses cracks is being introduced and used by stacking AlGaN materials containing an Al or Ga composition on the above-described melt-back etching prevention film region in an already known multilayered structure.

However, the crack prevention compressive stress layer having the above-described conventional group III nitride (GaN material-based) power semiconductor (HEMT) device structure has a problem that it is difficult to grow a high-quality and thick layer when forming AlGaN materials having a high Al ratio, and dislocations are caused by a deterioration in crystal quality, thereby promoting an increase in leakage current.

Third, in the conventional group III nitride (GaN material-based) power semiconductor (HEMT) device structure, to suppress a leakage current under the GaN channel layer, a GaN buffer layer heavily doped with impurities such as iron (Fe) or carbon (C) to have high resistance is typically formed.

However, according to the conventional group III nitride (GaN material-based) power semiconductor (HEMT) device structure, there is a problem that the crystal quality of the GaN materials greatly deteriorates due to excessively doped Fe or C impurities, and an increase in density of fatal crystal defects, that is, dislocations, promotes an increase in a leakage current. In addition, due to the low crystal quality of the GaN buffer layer, the GaN channel layer and AlGaN barrier layer that are grown on the GaN buffer layer in a continuous process also have a problem of low crystal quality.

Therefore, a GaN on sapphire method having the next best crystal quality after the power semiconductor device manufactured by a GaN on GaN method is widely used to improve crystal quality, and an epitaxial deposition technology in this method has already been developed and matured, but the only disadvantage of the GaN on sapphire method is that there is a limit to application to high-output products due to the poor heat dissipation capacity of sapphire.

To overcome this, high-power products have been conventionally developed using SiC and Si growth substrates having high heat dissipation performance, but are inferior to epitaxial products grown on the sapphire growth substrates in terms of performance, crystal quality, defects, and costs.

In addition, in order to improve the heat dissipation performance of a power semiconductor device, when a growth substrate is completely removed and a high heat dissipation support substrate is bonded, there is an advantage in that the heat dissipation performance of the power semiconductor device may be greatly improved. However, there is a problem that, during a process of removing the growth substrate and bonding the high heat dissipation support substrate, the long-term reliability of the power semiconductor device is adversely affected by thermo-mechanical shock or material diffusion.

### DISCLOSURE

### Technical Problem

The present invention is intended to solve the above-described conventional problems and is directed to providing a method of manufacturing a group 3 nitride semiconductor template having a high-quality group 3 nitride semiconductor seed layer, which can significantly improve the quality of a bonding layer by performing annealing on the bonding layer in two stages depending on a temperature.

### Technical Solution

According to the present invention, the above object is achieved by a method of manufacturing a group 3 nitride semiconductor template with improved bonding layer quality, which includes a growing operation of growing a seed layer on a growth substrate, an adhering operation of adhering one surface of the seed layer to a temporary substrate through an adhesive layer, a first removing operation of removing the growth substrate and exposing the other surface of the seed layer, a bonding operation of bonding the other surface of the seed layer to a support substrate through a bonding layer, a second removing operation of removing the temporary substrate, and a surface treating operation of removing the adhesive layer and exposing the one surface of the seed layer, wherein, in at least one of the bonding operation and the surface treating operation, annealing is performed on the bonding layer.

In addition, the annealing may be performed at a first temperature and then performed at a second temperature that is higher than the first temperature.

In addition, the first temperature may range from 300° C. to 700° C., and the second temperature may range from 700° C. to 1100° C.

In addition, the annealing may be performed at different stages depending on a material forming the support substrate.

In addition, the support substrate may be made of an AlN ceramic, Si, or SiC.

In addition, the annealing may be performed at the first temperature and then performed at the second temperature in the surface treating operation.

In addition, the support substrate may be made of sapphire or glass of which a coefficient of thermal expansion is adjusted.

In addition, the annealing may be performed at the first temperature and then performed at the second temperature in the bonding operation.

In addition, the annealing may be performed at the first temperature in the bonding operation and then performed at the second temperature in the surface treating operation.

In addition, the annealing may be performed at the first temperature and then performed at the second temperature in the surface treating operation.

In addition, the bonding operation may include forming a capture layer for capturing gas generated when the bonding layer is annealed.

In addition, the capture layer may be formed adjacent to at least one of upper and lower portions of the bonding layer.

### Advantageous Effects

According to the present invention, it is possible to significantly increase the bonding strength of a bonding layer of a group 3 nitride semiconductor growth template manufactured through a two-step wafer bonding and laser lift off (LLO) process.

In addition, according to the present invention, by-product gases (H2, H2O) generated by performing annealing on a bonding layer can be easily captured by a capture layer, thereby effectively preventing the occurrence of voids and bubbles inside the bonding layer.

Meanwhile, the effects of the present invention are not limited to the above-described effects, and may include various effects within a range that is apparent to those skilled in the art from the following descriptions.

### DESCRIPTION OF DRAWINGS

FIG. 1 is a flowchart of a method of manufacturing a group 3 nitride semiconductor template with improved bonding layer quality according to one embodiment of the present invention.

FIG. 2 shows that annealing is performed on a bonding layer in a surface treating operation during a process of manufacturing a group 3 nitride semiconductor template with improved bonding layer quality according to one embodiment of the present invention.

FIG. 3 shows that annealing is performed on a bonding layer in a bonding operation and a surface treating operation during the process of manufacturing a group 3 nitride semiconductor template with improved bonding layer quality according to one embodiment of the present invention.

FIG. 4 shows that annealing is performed on the bonding layer in a bonding operation during the process of manufacturing a group 3 nitride semiconductor template with improved bonding layer quality according to one embodiment of the present invention.

FIG. 5 shows that voids are generated in the bonding layer in the method of manufacturing a group 3 nitride semiconductor template with improved bonding layer quality according to one embodiment of the present invention.

FIG. 6 shows that a capture layer is formed adjacent to upper and lower portions of the bonding layer in the method of manufacturing a group 3 nitride semiconductor template with improved bonding layer quality according to one embodiment of the present invention.

### MODES OF THE INVENTION

Hereinafter, some embodiments of the present invention will be described in detail with reference to exemplary drawings. In adding reference numerals to components in each drawing, it should be noted that the same components have the same reference numerals as much as possible even when they are illustrated in different drawings.

In addition, in describing embodiments of the present invention, detailed descriptions of related known configurations or functions will be omitted when it is determined that the detailed descriptions obscure the understanding of the embodiments of the present invention.

In addition, terms such as first, second, A, B, (a), and (b) may be used to describe components of the embodiments of the present invention. These terms are only for the purpose of distinguishing one component from another component, and the nature, sequence, order, or the like of the corresponding component is not limited by the terms.

A method S100 of manufacturing a group 3 nitride semiconductor template with improved bonding layer quality according to one embodiment of the present invention will now be described in detail with reference to the accompanying drawings.

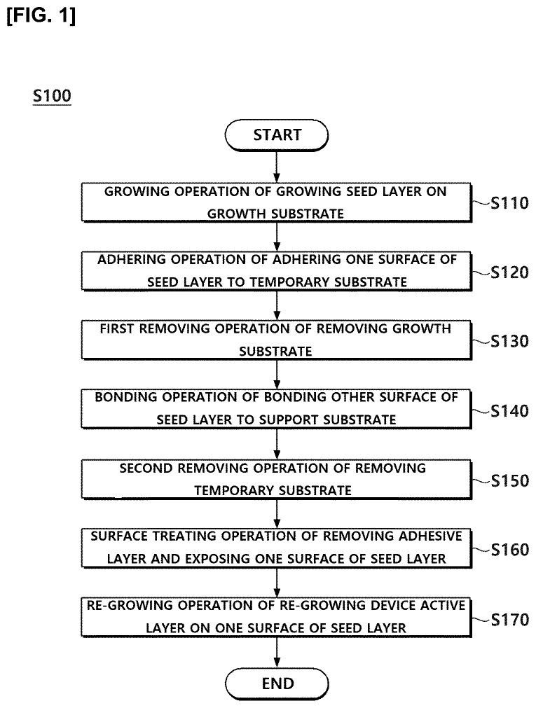

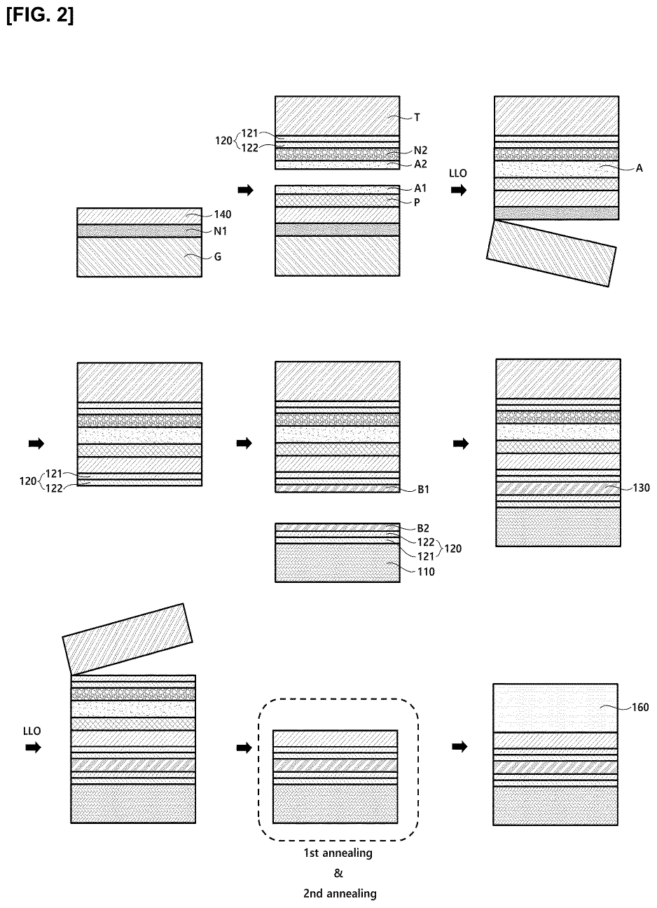

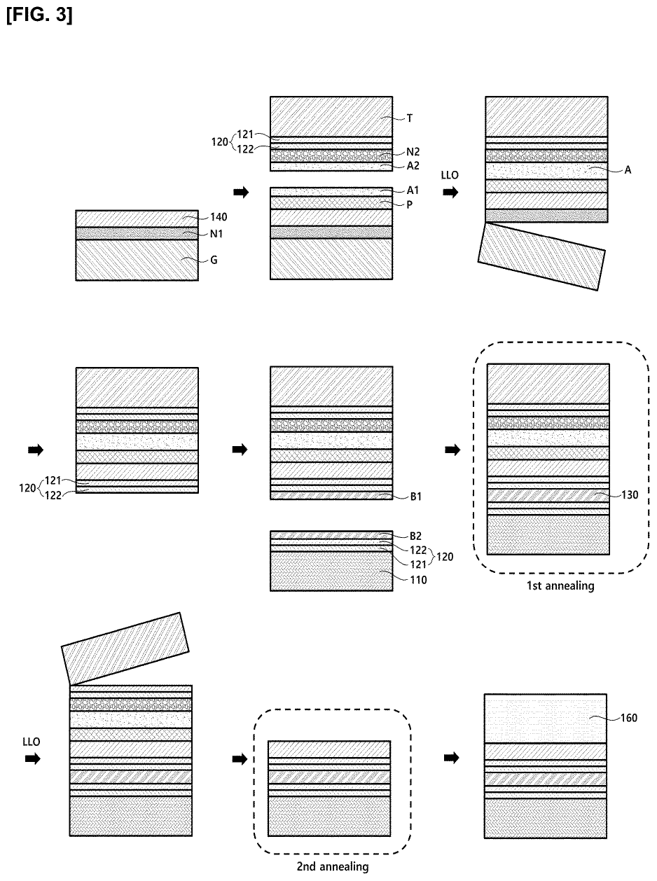

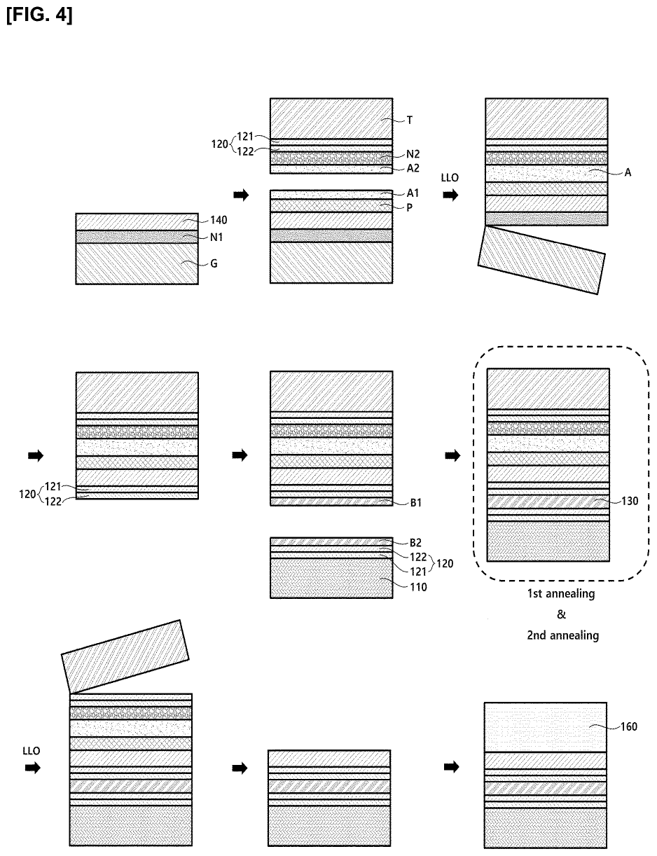

FIG. 1 is a flowchart of a method of manufacturing a group 3 nitride semiconductor template with improved bonding layer quality according to one embodiment of the present invention, FIG. 2 shows that annealing is performed on a bonding layer in a surface treating operation during a process of manufacturing a group 3 nitride semiconductor template with improved bonding layer quality according to one embodiment of the present invention, FIG. 3 shows that annealing is performed on a bonding layer in a bonding operation and a surface treating operation during the process of manufacturing a group 3 nitride semiconductor template with improved bonding layer quality according to one embodiment of the present invention, and FIG. 4 shows that annealing is performed on the bonding layer in a bonding operation during the process of manufacturing a group 3 nitride semiconductor template with improved bonding layer quality according to one embodiment of the present invention.

The present invention provides a growth template having a seed layer 140 with a defect-free, high-quality group III atomic polar surface through a two-step wafer bonding and laser lift off (LLO) process.

As shown in FIGS. 1 to 4, the method S100 of manufacturing a group 3 nitride semiconductor template with improved bonding layer quality according to one embodiment of the present invention includes a growing operation S110, an adhering operation S120, a first removing operation S130, a bonding operation S140, a second removing operation S150, a surface treating operation S160, and a re-growing operation S170.

The growing operation S110 is an operation of epitaxially growing the seed layer 140 on an initial growth substrate G.

Here, the initial growth substrate G is an optically transparent and high-temperature heat-resistant substrate through which a laser beam (single wavelength light) may be 100% transmitted (theoretically) without absorption in an LLO process to be described below, and a material such as sapphire (α-phase Al2O3), ScMgAlO4, 4H—SiC, or 6H—SiC is preferably used. In addition, the initial growth substrate G may be preferably provided as a patterned sapphire substrate (PSS) having a protrusion shape that is patterned regularly or irregularly in various dimensions (size and shape) in microscale or nanoscale to minimize crystal defects inside the group 3 nitride semiconductor thin film grown thereon.

More specifically, the growing operation S110 may include forming a first sacrificial layer N1 on the initial growth substrate G and then growing the seed layer 140 as a single layer or multiple layers on the first sacrificial layer N1. The first sacrificial layer N1 is a layer required for growing a high-quality group 3 nitride semiconductor seed layer 140 and may contain an oxide, a nitride, etc. that may be deposited by a physical vapor deposition (PVD) technique such as sputtering, pulsed laser deposition (PLD), or an evaporator as a material that may be sacrificed and separated due to thermal-chemical decomposition reactions caused by a laser beam and specifically, may contain a material such as ITO, GaOx, GaON, GaN, InGaN, ZnO, InGaZnO, InZnO, or InGaO. The first sacrificial layer N1 may be grown directly on the initial growth substrate G to minimize crystal defects in the group 3 nitride semiconductor seed layer 140 to serve as a buffer, and the seed layer 140 may also function as the first sacrificial layer N1.

In addition, the group 3 nitride semiconductor seed layer 140 grown on the initial growth substrate G is formed of a single layer or multiple layers of group 3 nitride semiconductors and may be made of GaN, AlGaN, InGaN, AlGaInN, AlN, Ga(In)N/nGa(In)N, GaN/InAlN, AlScN, GaN/AlScN, AlGaN/AlN SLs (super lattices), AlN/GaN SLs, AlGaN/GaN SLs, etc., which have high temperature (HT) and high resistance (HR) characteristics. The group 3 nitride semiconductor seed layer 140 is a critical quality factor in reducing the density of fatal crystal defects, that is, threading dislocations (present in a vertical direction with respect to the initial growth substrate G) (≤Low 108/cm2).

The adhering operation S120 is an operation of adhering one surface of the seed layer 140 to an intermediate temporary substrate T through an adhesive layer A.

Here, the intermediate temporary substrate T has a coefficient of thermal expansion (CTE) that is the same as or similar to that of a final support substrate 110 to be described below and at the same time, is made of an optically transparent material through which a laser beam (single wavelength light) may be 100% transmitted (theoretically) without absorption in an LLO process to be described below, and it is preferable that a difference in CTE from the final support substrate 110 does not exceed the maximum of 2 ppm. Sapphire is preferred as a material for the intermediate temporary substrate T, which satisfies the above, and glass whose CTE is adjusted to have a difference of 2 ppm or less from the final support substrate 110 may be included.

Typically, although the epitaxial wafer is in a bowing state in a concave shape due to the thermo-mechanical induced tensile stress caused by differences in LC and CTE between the growth substrate G and the group 3 nitride semiconductor, in the present invention, such a problem can be solved by strongly bonding the intermediate temporary substrate T to one surface of the grown group 3 nitride semiconductor seed layer 140 through the adhesive layer A. In this case, since a CTE value of the initial growth substrate G and the intermediate temporary substrate T are substantially the same, it is preferable to perform the adhering process to achieve strong bonding strength regardless of a temperature.

More specifically, the adhering operation S120 may include sequentially stacking an epitaxial protective layer P and a first adhesive layer A1 on one surface of the seed layer 140, sequentially stacking a reinforcement layer 120, a second sacrificial layer N2, and a second adhesive layer A2 on the intermediate temporary substrate T, and then temporarily pressing the first adhesive layer A1 and the second adhesive layer A2 to form the adhesive layer A. That is, the adhering operation S120 may include turning over the intermediate temporary substrate T on which the second adhesive layer A2 has been formed to separate the initial growth substrate G and pressing and adhering the intermediate temporary substrate T to the initial growth substrate G on which the first adhesive layer A1 has been formed at a temperature of lower than 300° C.

Here, the epitaxial protective layer P is a layer for preventing the seed layer 140 from being damaged during a subsequent process and may be made of a material in consideration of selective wet etching, and the epitaxial protective layer P may preferentially contain, for example, an oxide including SiO2, a nitride including SiNx, etc. and contain a metal, an alloy, etc. In addition, the second sacrificial layer N2 may be made of a material that is the same as or similar to that of the first sacrificial layer N1.

In addition, the adhesive layer A (including the first adhesive layer A1 and the second adhesive layer A2) may be made of a metal, alloy, ceramic, or resin material. In particular, for the adhesive layer A, a material capable of metallic bonding (eutectic bonding, diffusion bonding, direct bonding, etc.) may be preferably selected, and the adhesive layer A may contain a material such as In, Sn, Ga, Zn, Au, Ag, Cu, Pd, Ni, Ti, Cr, Al, or Si as a metallic bonding material capable of being soldered at a temperature of 300° C. or lower. In addition, the adhesive layer A may contain a material such as SiO2, spin on glass (SOG), a flowable oxide (FOx), SiNx, Al2O3, AlN, SiCN, ITO, IZO, or ZnO as a ceramic material capable of direct bonding at a temperature of 100° C. or lower and also contain a resin material such as an epoxy, benzocyclobutene (BCB), and polyimide (PI) as an organic adhesive capable of indirect bonding at a temperature of 100° C. or lower.

The first removing operation S130 is an operation of removing the growth substrate G using an LLO technique to expose the other surface of the seed layer 140.

Here, the LLO technique is a technique of separating an epitaxial-grown layer from the growth substrate G by irradiating a back surface of the transparent initial growth substrate G with an ultraviolet (UV) laser beam having a uniform optical output and beam profile, and a single wavelength. When the initial growth substrate G is separated, the inside of the group 3 nitride semiconductor seed layer 140 transferred onto the intermediate temporary substrate T is in a state in which the stress has been completely relieved and maintains a flat state together with the intermediate temporary substrate T. Then, it is preferable that a damaged region, contaminated surface residue, and low-quality single crystalline thin film region due to the separation of the initial growth substrate G is removed as completely as possible.

More specifically, the first removing operation S130 includes removing the initial growth substrate G using an LLO technique and then etching and removing the first sacrificial layer N1 to expose the other surface of the seed layer 140 that is a nitrogen polar surface, and the exposed other surface of the seed layer 140 needs to have a region that is locally damaged by a laser beam, and various shapes of surface crystal defects, such as V-shaped pits inevitably formed during the growth of the seed layer 140 or polarity inversion, are generated. Since the crystal defects and the damaged nitrogen polar surface result in great difficulties in bonding the final support substrate 110 to be described below and quality issues, to improve this, it is essential to perform a surface planarization process through ceramic material deposition and/or a chemical-mechanical polishing (CMP) process.

The bonding operation S140 is an operation of bonding the other surface of the seed layer 140 to the support substrate 110 through a bonding layer 130.

Here, the support substrate 110 is a substrate that supports the seed layer 140 and a device active layer 150 on the seed layer 140 after undergoing each operation of the method of manufacturing a group 3 nitride semiconductor template according to one embodiment of the present invention, and the support substrate 110 may be made of an AlN ceramic (AlNcera), Si, SiC, sapphire, or glass whose CTE is adjusted, and in particular, SiC and AlN may be a single crystalline or polycrystalline material. Meanwhile, the stage at which annealing is performed differs depending on the type of the support substrate 110, which will be described below.

In the past, epitaxial wafer bowing occurred due to the thermo-mechanical induced stress caused by differences in LC and CTE between the initial growth substrate G and the group 3 nitride semiconductor, however, in the present invention, the above problem can be solved by strongly bonding the final support substrate 110 to the other surface of the group 3 nitride semiconductor seed layer 140 through the bonding layer 130. That is, the epitaxial wafer to which the final support substrate 110 is bonded is in a stress-relieved state, and wafer bowing can be minimized to almost zero.

More specifically, the bonding operation S140 may include sequentially stacking a reinforcement layer 120 and a first bonding layer B1 on the other surface of the seed layer 140, sequentially stacking a reinforcement layer 120 and a second bonding layer B2 on the final support substrate 110, and then pressing the first bonding layer B1 and the second bonding layer B2 at a low temperature of room temperature to 200° C. or lower to form the bonding layer 130.

Here, the bonding layer 130 (including the first bonding layer B1 and the second bonding layer B2) may be preferentially selected from dielectric materials whose properties do not change and which have excellent thermal conductivity in the MOCVD chamber (at a temperature of 1000° C. or higher and in a reducing atmosphere) in which the group 3 nitride semiconductor is grown, may contain, for example, SiO2 (0.8 ppm), SiNx (3.8 ppm), SiCN (3.8 to 4.8 ppm), AlN (4.6 ppm), Al2O3 (6.8 ppm), and furthermore, may contain a flowable oxide (FOx) such as SOG (liquid SiO2) or HSQ to improve surface roughness.

In addition, the reinforcement layer 120 is a layer for increasing the bonding strength with the support substrate 110 and inducing compressive stress, and more specifically, the reinforcement layer 120 may include a bonding reinforcement layer 121 and a compressive stress layer 122.

The bonding reinforcement layer 121 is a layer introduced to increase bonding strength when the seed layer 140 is bonded to the final support substrate 110 through the bonding layer 130, and it is preferable to select a material constituting the bonding reinforcement layer 121 from SiO2, SiNx, etc.

The compressive stress layer 122 is made of a dielectric material with a value larger than the CTE of the final support substrate 110, for example, a material that relieves tensile stress, that is, induces compressive stress, such as AlN (4.6 ppm), AlNO (4.6 to 6.8 ppm), Al2O3 (6.8 ppm), SiC (4.8 ppm), SiCN (3.8 to 4.8 ppm), GaN (5.6 ppm), or GaNO (5.6 to 6.8 ppm), which serves to guide the quality improvement of products through stress control.

Meanwhile, in the present invention, the bonding reinforcement layer 121 or the compressive stress layer 122 may be omitted in some cases, and in some cases, the entire reinforcement layer 120 may be omitted so that the other surface of the seed layer 140 is in direct contact with the bonding layer 130 or the final support substrate 110 is in direct contact with the bonding layer 130. This case may be a structure that induces compressive stress together with a bonding function by depositing a material having a larger CTE than the final support substrate 110 on the bonding layer 130.

The second removing operation S150 is an operation of removing the temporary substrate T using an LLO technique. When the intermediate temporary substrate T is separated, the inside of the group 3 nitride semiconductor seed layer 140 transferred onto the final support substrate 110 is in a state in which the stress has been completely relieved and maintains a flat state together with the final support substrate 110.

The surface treating operation S160 is an operation of etching and removing the reinforcement layer 120, the second sacrificial layer N2, the adhesive layer A, and the epitaxial protective layer P to expose one surface of the seed layer 140, that is, a group III metal polar surface that has a hard surface and at the same time, is structurally and chemically stable. Here, the reinforcement layer 120, the second sacrificial layer N2, the adhesive layer A, and the epitaxial protective layer P may be formed through dry etching or wet etching, and it is preferable to remove the damaged area due to the separation of the intermediate temporary substrate T, contaminated surface residues, and a low-quality single crystalline thin film region as completely as possible.

The re-growing operation S170 is an operation of re-growing a group III nitride-based device active layer 150 for a power semiconductor device, a light-emitting device, or a communication filter device on the exposed one surface of the seed layer 140.

Meanwhile, at least one of the bonding operation S140 and the surface treating operation S160 may include performing annealing on the bonding layer 130. The bonding layer 130 of the present invention is in a state of being bonded at a low temperature of room temperature to 200° C. or lower and having weak bonding strength, and to increase the bonding strength of the bonding layer 130, annealing at a temperature of 300° C. or higher is required.

In this case, the annealing may be performed in stages, and specifically, the annealing may be first performed at a first temperature so that the bonding strength of the bonding layer 130 is primarily increased and then performed at a second temperature that is higher than the first temperature so that the bonding strength of the bonding layer 130 is secondarily increased. Here, the first temperature may range from 300° C. to 700° C., and the second temperature may range from 700° C. to 1100° C., but the present invention is not limited thereto.

Meanwhile, in the present invention, the stage at which annealing is performed may vary depending on a material forming the support substrate 110.

First, when the support substrate 110 is made of AlNcera, Si, or SiC, a difference in CTE of 2 ppm or more from the sapphire intermediate temporary substrate T occurs, and in this case, when annealing is performed at a high temperature of 300° C. or higher in the bonding operation S140 due to a large difference (2 ppm or more) in CTE, there may be an issue in which the intermediate temporary substrate T and the final support substrate 110 are separated from the weakly bonded bonding layer 130 made of a ceramic material. Therefore, in a case where the support substrate 110 is made of AlNcera, Si, or SiC, the annealing should be performed in a state in which the intermediate temporary substrate T has been removed, and thus as shown in FIG. 2, the annealing may be performed on the bonding layer 130 at the first temperature and the second temperature only in the surface treating operation S160.

In addition, in a case where the support substrate 110 is made of sapphire or glass whose CTE is adjusted, a difference in CTE from the sapphire intermediate temporary substrate T is less than 2 ppm, and thus even when the annealing is performed at a high temperature of 300° C. or higher in the bonding operation S140, the issue in which the intermediate temporary substrate T and the final support substrate 110 are separated does not occur. Therefore, when the support substrate 110 is made of sapphire or glass whose CTE is adjusted, the annealing may be performed in three ways, and specifically, annealing may be performed on the bonding layer 130 at the first temperature and the second temperature only in the surface treating operation S160 as shown in FIG. 2, annealing may be performed on the bonding layer 130 at the first temperature in the bonding operation S140 and then annealing may be performed on the bonding layer 130 at the second temperature in the surface treating operation S160 as shown in FIG. 3, or annealing may be performed on the bonding layer 130 at the first temperature and the second temperature only in the bonding operation S140 as shown in FIG. 4.

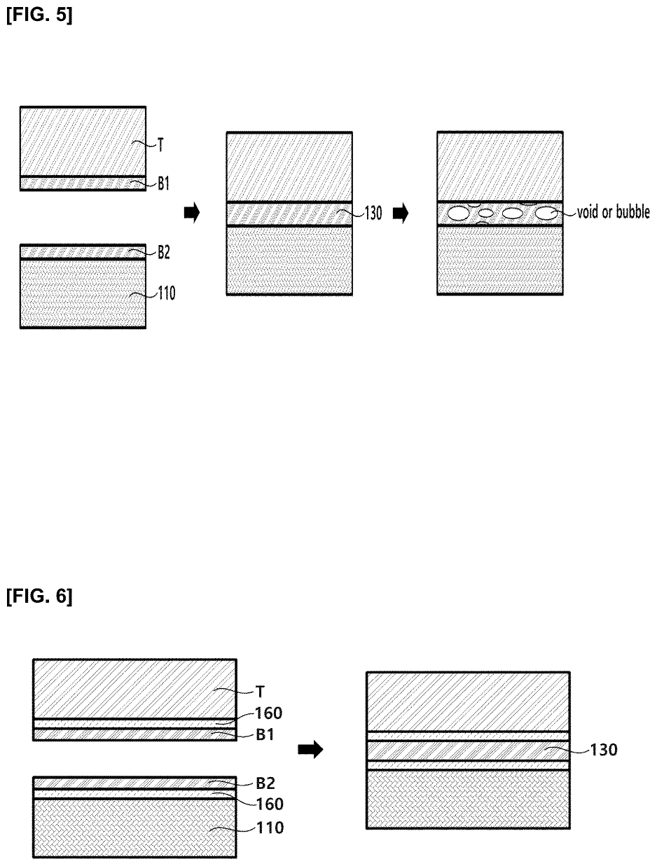

FIG. 5 shows that voids are generated in the bonding layer 130 in the method S100 of manufacturing a group 3 nitride semiconductor template with improved bonding layer quality according to one embodiment of the present invention.

As shown in FIG. 5, in the present invention, an oxide such as SiO2 or Al2O3 may be used as the material of the bonding layer 130, and in particular, SiO2 forms bonds between materials using a mechanism represented by Chemical Formula 1 below, and H2(g) and H2O(g) are generated as by-products of the bonding reaction, and thus voids or bubbles may be generated locally at a bonding portion, which may weaken bonding strength or cause delamination problems.

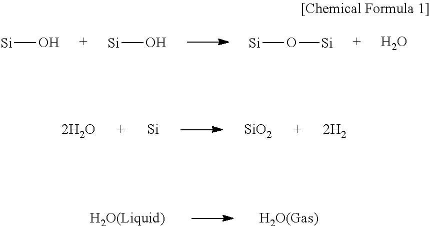

Generally, when the bonding layer 130 is made of SiO2 (in addition to Al2O3) oxide formed by a CVD or ALD method and then annealed at a high temperature of 300° C. or higher, there is a problem that a large amount of the above-described gas by-products are generated. Furthermore, the degrees (quantities) of by-product gases (H2, H2O) generated from the SiO2 (in addition to Al2O3) bonding material vary depending on an SiO2 formation method, and in the case of SiO2 deposited by the most commonly used plasma enhanced chemical vapor deposition (PECVD), there is a problem that voids or bubbles are generated more severely because more OH groups are contained inside the SiO2 bonding layer during the formation process.

Therefore, the bonding operation S140 may form a capture layer 160 for capturing gases generated when annealing is performed on the bonding layer 130.

FIG. 6 shows that the capture layer 160 is formed adjacent to upper and lower portions of the bonding layer 130 in the method S100 of manufacturing a group 3 nitride semiconductor template with improved bonding layer quality according to one embodiment of the present invention.

As shown in FIG. 6, in the bonding operation S140 of the present invention, the capture layer 160 may be introduced at a location adjacent to at least one of the upper and lower portions of the SiO2 (in addition to Al2O3) bonding layer 130 deposited by the CVD method to capture by-product gases (H2, H2O) during high-temperature annealing at 300° C. or higher, thereby effectively suppressing the generation of a large number of voids or bubbles inside the SiO2 (in addition to Al2O3) bonding layer 130.

More specifically, the bonding operation S140 may include sequentially stacking a capture layer 160 and a first bonding layer B1 on the other surface of the seed layer 140, sequentially stacking a capture layer 160 and a second bonding layer B2 on the final support substrate 110, and then pressing the first bonding layer B1 and the second bonding layer B2 at a low temperature of room temperature to 200° C. or lower to form the bonding layer 130. Meanwhile, the stacking order of the reinforcement layer 120 and the capture layer 160 is not limited.

The capture layer 160 may contain Si, a silicide, Ge, SiGe, Ti, Nb, V, Pd, and Fe as a material that facilitates the diffusion of the by-product gases (H2, H2O), and any material that may easily capture the by-product gases (H2, H2O) may be used.

As described above, although all the components constituting embodiments of the present invention were described as being combined or combined to operate as one, the present invention is not necessarily limited to these embodiments. That is, one or more of all the components may be combined to operate as one without departing from the scope of the purpose of the present invention.

In addition, the terms such as “comprise,” “constitute,” or “have” described above mean that the corresponding component may be inherent unless otherwise stated, and thus should be construed as further including another component rather than excluding another component. All terms including technical or scientific terms have the same meaning as commonly understood by those skilled in the art to which the present invention pertains unless defined otherwise. Commonly used terms, such as terms defined in a dictionary, should be intended as being consistent with the contextual meaning of the related art and are not interpreted in an ideal or excessively formal meaning unless explicitly defined herein.

In addition, the above description is merely the exemplary description of the technical spirit of the present invention, and those skilled in the art to which the present invention pertains will be able to variously modify and change the present invention without departing from the essential characteristics of the present invention.

Therefore, the embodiments disclosed in the present invention are not intended to limit the technical spirit of the present invention, but intended to describe the same, and the scope of the technical spirit of the present invention is not limited by these embodiments. The scope of the present invention should be construed by the appended claims, and all technical ideas within the equivalent scope should be construed as being included in the scope of the present invention.

1. A method of manufacturing a group 3 nitride semiconductor template with improved bonding layer quality, the method comprising:
a growing operation of growing a seed layer on a growth substrate;
an adhering operation of adhering one surface of the seed layer to a temporary substrate through an adhesive layer;
a first removing operation of removing the growth substrate and exposing the other surface of the seed layer;
a bonding operation of bonding the other surface of the seed layer to a support substrate through a bonding layer;
a second removing operation of removing the temporary substrate; and
a surface treating operation of removing the adhesive layer and exposing the one surface of the seed layer,
wherein, in at least one of the bonding operation and the surface treating operation, annealing is performed on the bonding layer.

2. The method of claim 1, wherein the annealing is performed at a first temperature and then performed at a second temperature that is higher than the first temperature.

3. The method of claim 2, wherein the first temperature ranges from 300° C. to 700° C., and
the second temperature ranges from 700° C. to 1100° C.

4. The method of claim 2, wherein the annealing is performed at different stages depending on a material forming the support substrate.

5. The method of claim 4, wherein the support substrate is made of an AlN ceramic, Si, or SiC.

6. The method of claim 5, wherein the annealing is performed at the first temperature and then performed at the second temperature in the surface treating operation.

7. The method of claim 4, wherein the support substrate is made of sapphire or glass of which a coefficient of thermal expansion is adjusted.

8. The method of claim 7, wherein the annealing is performed at the first temperature and then performed at the second temperature in the bonding operation.

9. The method of claim 7, wherein the annealing is performed at the first temperature in the bonding operation and then performed at the second temperature in the surface treating operation.

10. The method of claim 7, wherein the annealing is performed at the first temperature and then performed at the second temperature in the surface treating operation.

11. The method of claim 1, wherein the bonding operation includes forming a capture layer for capturing gas generated when the bonding layer is annealed.

12. The method of claim 11, wherein the capture layer is formed adjacent to at least one of upper and lower portions of the bonding layer.
